(19) United States
(12) Patent Application Publication
(10) Pub. No.: US 2008/0264485 A1
(43) Pub. Date: Oct. 30, 2008

(54) DYE-SENSITIZED SOLAR CELL CONTAINING FLUORESCENT MATERIAL AND METHOD OF MANUFACTURING THE SAME

(75) Inventors: Kyung Hee Park, Gwangju (KR); Hyung Gon Jeong, Gwangju (KR); Hal Bon Gu, Gwangju (KR); Sung Yong Cho, Gwangju (KR)

Correspondence Address: LEE, HONG, DEGERMAN, KANG & SCHMADEKA, 660 S. FIGUEROA STREET, Suite 2300, LOS ANGELES, CA, 90017, US

(73) Assignees: INDUSTRY FOUNDATION OF CHONNAM NATIONAL UNIVERSITY; INNOFILTER CO., LTD.

(21) Appl. No.: 12/029,682

(22) Filed: Feb. 12, 2008

(30) Foreign Application Priority Data
Apr. 27, 2007 (KR) 10-2007-0041183
Aug. 20, 2007 (KR) 10-2007-0083421

(51) Int. Cl. H01L 31/0224; B32B 37/14

(52) U.S. Cl. 136/256; 156/145

(57) ABSTRACT

Provided are a dye-sensitized solar cell and a method of manufacturing the same. The dye-sensitized solar cell includes an opposing electrode and a photoelectrode. The opposing electrode includes a light-transmitting layer formed of a transparent glass substrate and an FTO (fluorine-doped tin oxide) thin film deposited on the transparent glass substrate, and a catalyst layer formed by depositing platinum on the FTO thin film. The photoelectrode includes a glass substrate and an FTO thin film deposited on the glass substrate. The photoelectrode is coated with a mixture of a fluorescent material and a transition metal oxide that includes titanium dioxide (TiO₂) to thereby be adsorbed with a dye. An electrolyte is filled between the opposing electrode and the photoelectrode. According to the present invention, by introducing the fluorescent material to the photoelectrode portion of the dye-sensitized solar cell, a high energy conversion efficiency is obtained due to illumination characteristics of the fluorescent material in the visible spectrum.

### CROSS-REFERENCE TO RELATED APPLICATION

This application claims priority from Korean Patent Application No. 10-2007-0041183 filed on Apr. 27, 2007 and No. 10-2007-0083421 filed on Aug. 20, 2007 in the Korean Intellectual Property Office, the disclosure of which is incorporated herein by reference in its entirety.

### BACKGROUND OF THE INVENTION

1. Field of the Invention

The present invention relates to a dye-sensitized solar cell containing fluorescent material and a method of manufacturing the same.

2. Description of the Related Art

A dye-sensitized solar cell is a new type of solar cell having a high energy conversion efficiency and that may be manufactured at a low cost. A dye-sensitized solar cell is one type of solar cell that utilizes the sunlight absorption capability of dye to chemically generate electricity. The dye-sensitized solar cell is formed of a photoelectrode that includes a metal oxide and a dye provided on a transparent glass substrate, an electrolyte, and an opposing electrode.

The photoelectrode, which is present in the form of a porous film, is formed of an n-type transition metal oxide semiconductor having a large band gap, such as TiO₂, ZnO, and SnO₂, and a dye of a monomolecular layer is adsorbed to a surface thereof. When sunlight is irradiated onto the solar cell, electrons near the Fermi energy in the dye absorb the solar energy and are excited to an upper level that is not full of electrons. At this time, holes in the lower level from where the electrons escaped are again filled by electrons provided by ions in the electrolyte. The ions that provide electrons to the dye move to the photoelectrode to thereby receive electrons. During this process, the photoelectrode operates as a catalyst for an oxidation-reduction reaction of the ions in the electrolyte to thereby function to provide electrons to the ions in the electrolyte via the oxidation-reduction reaction on the surface of the photoelectrode.

In order to enhance the energy conversion efficiency in the conventional dye-sensitized solar cell, a platinum thin film that provides for a superior catalytic effect is typically used. Also used are electrodes that utilize precious metals such as palladium, silver, and gold, which have characteristics similar to that of platinum, and electrodes utilizing carbon-based materials such as carbon black and graphite. However, the dye-sensitized solar cell using the conventional platinum electrode as the opposing electrode nevertheless continues to suffer from a low efficiency with respect to converting sunlight into electrical energy. Hence, various ways to improve the efficiency of the solar cell are being explored.

### SUMMARY OF THE INVENTION

Aspects of the present invention provide a dye-sensitized solar cell and a method of manufacturing the same, in which a fluorescent material is mixed in a photoelectrode portion of the dye-sensitized solar cell to thereby obtain a high energy conversion efficiency (of two times or greater) due to illumination characteristics of the fluorescent material in the visible spectrum.

Aspects of the present invention also provide a dye-sensitized solar cell and a method of manufacturing the same, in which light is emitted in dark areas as a result of fluorescent material contained in a photoelectrode of the dye-sensitized solar cell, such that the dye-sensitized solar cell simultaneously functions to provide an advertising effect in the dark.

However, the aspects of the present invention are not restricted to the one set forth herein. The above and other aspects of the present invention will become more apparent to one of daily skill in the art to which the present invention pertains by referencing a detailed description of the present invention given below.

According to an aspect of the present invention, there is provided a dye-sensitized solar cell including an opposing electrode and a photoelectrode. The opposing electrode includes a light-transmitting layer formed of a transparent glass substrate and an FTO (fluorine-doped tin oxide) thin film deposited on the transparent glass substrate, and a catalyst layer formed by depositing platinum on the FTO thin film. The photoelectrode includes a glass substrate and an FTO thin film deposited on the glass substrate. The photoelectrode is coated with a mixture of a fluorescent material and a transition metal oxide that includes titanium dioxide to thereby be adsorbed with a dye. Furthermore, the opposing electrode and the photoelectrode are sealed using an adhesive film, and an electrolyte is filled between the opposing electrode and the photoelectrode. The fluorescent material of the photoelectrode may be at least one of tungstate, silicate, and borate, to thereby be adsorbed with a dye; and

Preferably, the fluorescent material of the photoelectrode is provided by an amount that is 0.01 to 20 wt. parts based on 100 parts by wt. of a photoelectrode paste solid that is formed by mixing the transition metal oxide and the fluorescent material. Also, preferably, the fluorescent material is a lanthanum-based material of YAG (Yttrium Aluminum Garnet: Y₃Al₅O₁₂) that emits light in the visible spectrum, the lanthanum-based material being formed of a dye selected from the group consisting of La, Ce, Pr, Nd, Sm, Eu, Y, and Ho ions and elements, and mixtures thereof.

According to another aspect of the present invention, there is provided a method of manufacturing a dye-sensitized solar cell including: producing a photoelectrode paste by mixing a transition metal oxide and a fluorescent material; producing a photoelectrode by coating the paste on an FTO (fluorine-doped tin oxide)-treated transparent glass substrate, and following drying and heat-treating of the transparent glass substrate, adsorbing a dye thereto; producing an opposing electrode by coating a platinum layer on an FTO-treated glass substrate; and sealing the photoelectrode and the opposing electrode using an adhesive film, and filling an electrolyte in a space between the photoelectrode and the opposing electrode.

In the step of producing the photoelectrode paste, preferably, agitation is performed through 20 cycles, in which each cycle includes 12-18 minutes of agitation and 2-7 minutes of rest.

### BRIEF DESCRIPTION OF THE DRAWINGS

The above and other aspects and features of the present invention will become more apparent by describing in detail exemplary embodiments thereof with reference to the attached drawings, in which:

FIG. 1 is a sectional view of a dye-sensitized solar cell according to an embodiment of the present invention;

FIG. 2 is a graph showing current-voltage curves of an Example of the present invention and of Comparative Examples; and

FIG. 3 is a graph showing how current-voltage curves vary depending on the amount of fluorescent material used in the dye-sensitized solar cell of the present invention.

### DETAILED DESCRIPTION OF THE EXEMPLARY EMBODIMENTS

The present invention will now be described more fully with reference to the accompanying drawings, in which exemplary embodiments of the invention are shown. The invention may, however, be embodied in many different forms and should not be construed as being limited to the embodiments set forth herein. Rather, these embodiments are provided so that this disclosure will be thorough and complete, and will fully convey the concept of the invention to those skilled in the art.

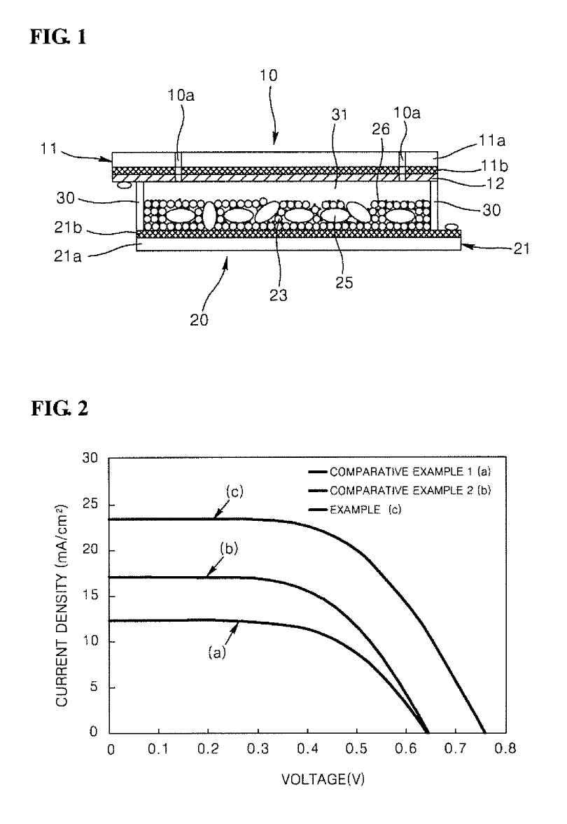

FIG. 1 is a sectional view of a dye-sensitized solar cell according to an embodiment of the present invention. Referring to FIG. 1, the dye-sensitized solar cell according to an embodiment of the present invention includes an opposing electrode 10 and a photoelectrode 20. The opposing electrode 10 includes a light-transmitting layer 11 formed of a transparent glass substrate 11a and an FTO (fluorine-doped tin oxide) thin film 11b deposited on the transparent glass substrate 11a, and a catalyst layer 12 formed by depositing platinum on the FTO thin film 11b. The photoelectrode 20 includes a glass substrate 21a and an FTO thin film 21 deposited on the glass substrate 21a. The photoelectrode 20 is coated with a paste formed by mixing titanium dioxide 23, polyethylene glycol, TritonX-100, acetylacetone, ethanol, water, nitric acid, and a fluorescent material 25. After drying and heat-treating the paste, a dye 26 is adsorbed to the photoelectrode 20. Subsequently, an adhesive film 30 is positioned between the opposing electrode 10 and the photoelectrode 20, and a heat transfer machine is used to seal the opposing electrode 10 and the photoelectrode 20. Finally, an electrolyte 31 including a redox couple (typically 1⁻/I₃⁻) is filled through small holes 10a formed through the opposing electrode 10.

An important feature of the present invention relates to the introduction of the fluorescent material during manufacture of the photoelectrode. A key function of the fluorescent material is that of enhancing the energy conversion efficiency of the dye-sensitized solar cell of the present invention. Also, by exhibiting illumination characteristics when there is only a small amount of sunlight, the fluorescent material provides the solar cell with an additional function. For example, during the day, the solar cell functions in the normal fashion to generate electricity, while at night, the fluorescent material emits light so that the solar cell can provide an advertising effect.

In addition, a method of manufacturing a dye-sensitized solar cell containing a fluorescent material according to an embodiment of the present invention includes producing a photoelectrode paste by agitating titanium dioxide (Degussa P-25), polyethylene glycol (molecular weight of 20,000), TritonX-100, and ethanol with a nitric acid solution, and after agitating acetylacetone with water, adding YAG (Ce) (Yttrium Aluminum Garnet: Y₃Al₅O₁₂) and again performing agitation. The method also includes: producing a photoelectrode by coating the paste on an FTO (fluorine-doped tin oxide)-treated glass substrate, and following drying and heat-treating of the transparent glass substrate, adsorbing a dye thereto; producing an opposing electrode by coating a platinum layer on an FTO-treated glass substrate; and sealing the photoelectrode and the opposing electrode using an adhesive film, and filling an electrolyte in a space between the photoelectrode and the opposing electrode.

### EXAMPLE

The dye-sensitized solar cell of the present invention was manufactured in the following manner. Titanium dioxide in the amount of 2 g, 0.4 g of polyethylene glycol (molecular weight of 20,000), 0.1 g of TritonX-100, 1 ml of a nitric acid solution, 2 ml of ethanol, 0.2 g of acetylacetone, and 7 ml of distilled water were placed in a spin agitator, and then the agitator was started. Agitation was performed through 20 cycles, in which each cycle included 15 minutes of agitation and 5 minutes of rest. Subsequently, fluorescent material of YAG(Ce) was added to thereby make a photoelectrode paste solid. The amount of YAG(Ce) was 10 wt. parts based on 100 parts by wt. of the photoelectrode paste solid. Ten more agitation cycles were then performed to thereby produce a photoelectrode paste containing the fluorescent material. Next, the paste was coated on an FTO-treated transparent glass substrate, after which drying was performed for 30 minutes at 80° C. to thereby perform an initial heat-treating process. Next, a secondary heat-treating process was performed for 30 minutes at a temperature of 450° C. to thereby produce a photoelectrode. Two small holes, through which an electrolyte is to be subsequently injected, were then formed in a substrate coated with FTO, after which platinum in the form of a thin film was coated on the substrate to thereby produce an opposing electrode. An adhesive film was disposed between the opposing electrode and the photoelectrode, after which the opposing electrode and the photoelectrode were sealed through the application of heat. Next, a liquid electrolyte was injected through the small holes formed in the opposing electrode, after which the small holes were sealed, thus completing the dye-sensitive solar cell. In order to improve the energy conversion efficiency of the solar cell, the amount of the fluorescent material YAG(Ce) is preferably 0.01 to 20 wt. parts based on 100 parts by wt. of the photoelectrode paste solid, and more preferably, 0.1 to 10 wt. parts based on 100 parts by wt. of the photoelectrode paste solid.

### COMPARATIVE EXAMPLES

Except for omitting the fluorescent material YAG(Ce) from the configuration of the photoelectrode, a sample for use as Comparative Example 1 was made identically as the Example, and a sample for use as Comparative Example 2 was made by irradiating UV (ultraviolet) light following the secondary heat-treating process during production of the photoelectrode. Comparative Examples 1 and 2 were compared with the Example of the present invention.

Table 1 compares electrical characteristics of samples that include a photoelectrode made using known methods with those of a sample made according to the present invention. The sample including a photoelectrode containing fluorescent material and made according to the present invention exhibited superior electrical characteristics. In the conventional configuration, an improvement in energy conversion efficiency has been reported when UV light is irradiated following heat-treating during manufacture of the photoelectrode. The sample utilizing such a conventional technique has also been compared.

Table 2 illustrates how electrical characteristics among samples produced according to the present invention varied depending on the amount of the fluorescent material (in parts by weight) used.

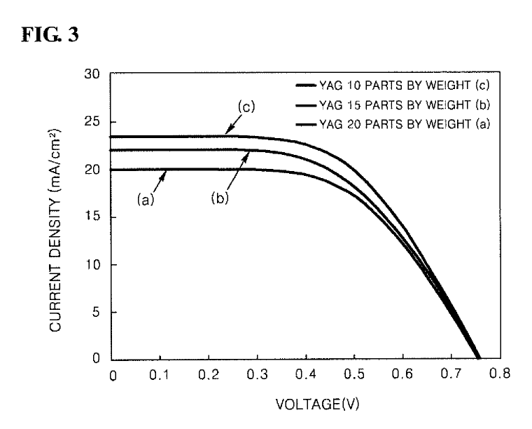

Reference is also made to FIG. 2 which shows current-voltage curves of the Example of the present invention and of Comparative Examples 1 and 2, and FIG. 3 which shows how current-voltage curves vary depending on the amount of fluorescent material used in the dye-sensitized solar cell of the present invention.

TABLE 1
Open-Circuit Voltage and Energy Conversion Efficiency

| | | | | Energy |
|---|---|---|---|---|
| | | | | Conversion |
| | Open-circuit | Current | | Efficiency |
| Sample | voltage (V) | density (mA/cm²) | Fill Factor | (%) |
| Comparative | 0.64 | 12.3 | 0.55 | 4.3 |
| Example 1 | | | | |
| Comparative | 0.64 | 17.1 | 0.52 | 5.7 |
| Example 2 | | | | |
| Example | 0.75 | 23.4 | 0.52 | 9.1 |

TABLE 2
Energy Conversion Efficiency Depending on Content of
Fluorescent Material YAG(Ce)

| Fluorescent | | | | Energy |
|---|---|---|---|---|
| material | Open-circuit | Current density | Fill | Conversion |
| content | voltage (V) | (mA/cm²) | Factor | Efficiency (%) |
| YAG 10 parts | 0.75 | 23.4 | 0.52 | 9.1 |
| by weight | | | | |
| YAG 15 parts | 0.75 | 21.9 | 0.49 | 8.0 |
| by weight | | | | |
| YAG 20 parts | 0.75 | 20.0 | 0.51 | 7.7 |
| by weight | | | | |

As described above, according to the present invention, by introducing fluorescent material in a photoelectrode of a dye-sensitive solar cell, a high energy conversion efficiency of the solar cell is obtained due to the light-emitting characteristics of the fluorescent material in the visible spectrum.

While the present invention has been particularly shown and described with reference to exemplary embodiments thereof it will be understood by those of ordinary skill in the art that various changes in form and details may be made therein without departing from the spirit and scope of the present invention as defined by the following claims.

What is claimed is:

1. A dye-sensitized solar cell comprising:
an opposing electrode that includes a light-transmitting layer formed of a transparent glass substrate and an FTO (fluorine-doped tin oxide) thin film deposited on the transparent glass substrate, and a catalyst layer formed by depositing platinum on the FTO thin film; and
a photoelectrode that includes a glass substrate and an FTO thin film deposited on the glass substrate,
wherein the photoelectrode is coated with a mixture of a fluorescent material and a transition metal oxide that includes titanium dioxide to thereby be adsorbed with a dye, and
wherein the opposing electrode and the photoelectrode are sealed using an adhesive film, and an electrolyte is filled between the opposing electrode and the photoelectrode.

2. The dye-sensitized solar cell of claim 1, wherein the fluorescent material of the photoelectrode is provided by an amount that is 0.01 to 20 wt. parts based on 100 parts by wt. of a photoelectrode paste solid that is formed by mixing the transition metal oxide and the fluorescent material.

3. The dye-sensitized solar cell of claim 1, wherein the fluorescent material is a lanthanum-based material of YAG (Yttrium Aluminum Garnet: Y₃Al₅O₁₂) that emits light in the visible spectrum, the lanthanum-based material being formed of a dye selected from the group consisting of La, Ce, Pr, Nd, Sm, Eu, Y, and Ho ions and elements, and mixtures thereof.

4. A dye-sensitized solar cell comprising:
an opposing electrode that includes a light-transmitting layer formed of a transparent glass substrate and an FTO (fluorine-doped tin oxide) thin film deposited on the transparent glass substrate, and a catalyst layer formed by depositing platinum on the FTO thin film; and
a photoelectrode that includes a glass substrate and an FTO thin film deposited on the glass substrate,
wherein the photoelectrode is coated with a mixture of a fluorescent material of at least one of tungstate, silicate, and borate, and a transition metal oxide that includes titanium dioxide to thereby be adsorbed with a dye, and
wherein the opposing electrode and the photoelectrode are sealed using an adhesive film, and an electrolyte is filled between the opposing electrode and the photoelectrode.

5. A method of manufacturing a dye-sensitized solar cell comprising:
producing a photoelectrode paste by mixing a transition metal oxide and a fluorescent material;
producing a photoelectrode by coating the paste on an FTO (fluorine-doped tin oxide)-treated transparent glass substrate, and following drying and heat-treating of the transparent glass substrate, adsorbing a dye thereto;
producing an opposing electrode by coating a platinum layer on an FTO-treated glass substrate; and
sealing the photoelectrode and the opposing electrode using an adhesive film, and filling an electrolyte in a space between the photoelectrode and the opposing electrode.

6. The method of claim 5, wherein the producing of the photoelectrode paste is implemented with 20 cycles of agitation, in which each cycle includes 12-18 minutes of agitation and 2-7 minutes of rest.
